(19) United States
(12) Patent Application Publication
(10) Pub. No.: US 2025/0254829 A1
(43) Pub. Date: Aug. 7, 2025

(54) VAPOR CHAMBER

(71) Applicant: PURPLE CLOUD DEVELOPMENT PTE. LTD., Singapore (SG)

(72) Inventors: XUE MEI WANG, Hui Zhou City (CN); YU WEI HAO, Hui Zhou City (CN)

(73) Assignee: PURPLE CLOUD DEVELOPMENT PTE. LTD., Singapore (SG)

(21) Appl. No.: 19/044,146

(22) Filed: Feb. 3, 2025

(30) Foreign Application Priority Data
Feb. 1, 2024 (CN) 2024101478442

(51) Int. Cl. H05K 7/20

(52) U.S. Cl. CPC H05K 7/20336

(57) ABSTRACT

A vapor chamber may include a first plate, evaporator wick structure, second plate, condenser wick structure, and plurality of heat pipes. The first plate includes a first inner surface, a first outer surface, and plurality of chamber walls extending from the first inner surface and having second and third chamber walls. The evaporator wick structure is disposed on the first inner surface. The condenser wick structure is disposed on a second inner surface of the second plate. The second plate is coupled to the plurality of chamber walls and plurality of heat pipes. At least one set of the heat pips is disposed through one chamber wall and another set of the heat pipes is disposed through the opposite chamber wall. Each of the heat pipes includes an inner chamber surface and pipe wick structure. The pipe wick structure is disposed on the inner chamber surface and coupled to the evaporator wick structure.

### RELATED APPLICATIONS

This U.S. application claims the benefit of priority to the Chinese application no. 202410147844.2, filed on Feb. 1, 2024. The Chinese application no. 202410147844.2 is hereby incorporated herein in its entirety.

### TECHNICAL FIELD

The present disclosure relates to thermal management of electronic systems in general and more particularly but not limited to vapor chambers.

### BACKGROUND

With the increase of the processing speed and performance of electronic components for electronic devices, such as application-specific integrated circuits (ASICs) and central processing units (CPUs) for electronic devices, the amount of heat generated during operation of the electronic devices increases. The generated heat increases the temperature of the electronic devices, including the electronic components thereof, and, if the heat cannot be dissipated effectively, the reliability and performance of the electronic devices are reduced.

To prevent overheating of electronic components of thin and compact electronic devices, vapor chambers may be used. The heat generated by an electronic component is conducted from a small and limited area of the electronic component to a greater area of the vapor chamber, and the generated heat may be dispersed inefficiently along the vapor chamber. Consequently, the vapor chamber may not adequately cool the electronic component, which could cause it to overheat.

### SUMMARY

According to certain aspects of the present disclosure, examples of vapor chambers include extension portions and extension wick portions of heat pipes into a vapor chamber, thereby speeding up the transport of working fluid back to a heat source.

In some aspects, the technique described herein related to a vapor chamber that includes: a first plate including a first outer surface, a first inner surface, and a first surface having a first plate perimeter portion; a chamber wall located along the first perimeter portion, extending from the inner first surface, and defining multiple openings; support structures extending from the first inner surface; an evaporator wick structure disposed on the first surface; a second plate including a second a second outer surface, a second inner surface opposing the first inner surface and having a second plate perimeter portion coupled to the chamber wall; a condenser wick structure disposed on the second inner surface; and heat pipes, each extending through a respective opening defined in the chamber wall and including an inner pipe wick structure coupled to the evaporator wick structure.

In some aspects, the technique described herein related to the vapor chamber described above, wherein the first plate, second plate, and chamber wall define an interior cavity including a heat exchange portion and a evaporation portion, the heat exchange portion disposed around the center of the interior cavity, the evaporation portion surrounding the heat exchange portion in the interior cavity, wherein each or the heat pipes is fluidly coupled to the interior cavity.

In some aspects, the technique described herein related to the vapor chamber described above, further including a core condenser wick structure coupled to the condenser wick structure and disposed in the interior cavity, and being disposed in the heat exchanger portion.

In some aspects, the technique described herein related to the vapor chamber described above, wherein each of the heat pipes includes a closed end disposed outside the interior cavity, an open end disposed in the interior cavity, and a connector portion coupling the open end of the heat pipe with the interior cavity.

In some aspects, the technique described herein related to the vapor chamber described above, wherein the first plate includes heat exchange structures extending from the first inner surface and disposed in the heat exchange portion.

In some aspects, the technique described herein related to the vapor chamber described above, wherein the heat exchange structures being integrally formed with the support structures.

In some aspects, the technique described herein related to the vapor chamber described above, wherein the heat transfer structures are elongated and disposed in parallel to the heat pipes.

In some aspects, the technique described herein related to the vapor chamber described above, wherein at least one of the heat pipes includes an extension portion at the opening end, the extension portion includes a bottom surface and an exposed portion of the inner pipe wick structure, the exposed portion not being enclosed within the heat pipe and being coupled to the pipe wick portion enclosed in the heat pipe and coupled to the evaporator wick structure.

In some aspects, the technique described herein related to the vapor chamber described above, wherein the bottom surface of the extension portion is coupled to the first inner surface, or to the evaporator wick structure.

In some aspects, the technique described herein related to the vapor chamber described above, wherein the evaporator wick structure includes a heat transfer wick portion disposed on the heat transfer structures, the extension wick portion being coupled to the heat transfer wick portion.

In some aspects, the technique described herein related to the vapor chamber described above, wherein each of the at least one extension portion is coupled to a respective set of the heat exchanger structures.

In some aspects, the technique described herein related to the vapor chamber described above, wherein each of the at least one extension portion includes a connector end and a cavity end, the connector end coupled to the connector portion, and the cavity end defining at least one a base cut out coupling a respective one of the heat transfer structures.

In some aspects, the technique described herein related to the vapor chamber described above, wherein the extension portion and the heat exchanger structures are separated by a vapor gap.

In some aspects, the technique described herein related to the vapor chamber described above, wherein the support structures abut the second surface.

In some aspects, the technique described herein related to the vapor chamber described above, wherein the evaporator wick structure, condenser wick structure, and inner pipe wick structure can each include a grooved wick, a sintered metal powder wick, a metal mesh wick, a sintered ceramic powder wick, or a combination thereof.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of vapor chambers incorporating aspects of the presently disclosed principles are illustrated by way of example, and not by way of limitation.

FIG. 1A illustrates a vapor chamber according to one aspect of the present disclosure.

FIG. 1B is an exploded view of the vapor chamber of FIG. 1A, according to one aspect of the present disclosure.

FIG. 2 illustrates a first plate of the vapor chamber of FIGS. 1A and 1B, according to an aspect of the present disclosure.

FIG. 3 illustrates a top view of the heat pipes and the second plate of the vapor chamber illustrated in FIGS. 1A, 1B, and 2 according to an aspect of the present disclosure.

FIG. 4 is a detailed view of the area marked “A” in FIG. 3, according to an aspect of the present disclosure.

FIG. 5 is a cross-sectional view of a heat pipe shown in FIGS. 1A, 1B, and 3 according to an aspect of the present disclosure.

FIG. 6 is a cross-sectional view of an alternative heat pipe shown in FIGS. 1A, 1B, and C according to an aspect of the present disclosure.

FIG. 7 is a cross-sectional view of another alternative heat pipe shown in FIGS. 1A, 1B, and C according to an aspect of the present disclosure.

FIG. 8 illustrates an alternative arrangement of heat pipes relative to the second plate of the vapor chamber shown in FIGS. 1A and 1B, according to an aspect of the present disclosure.

FIG. 9 is a detailed view of the area marked “B” in FIG. 8, according to an aspect of the present disclosure.

### DETAILED DESCRIPTION

The following describes various principles related to vapor chambers by way of reference to specific examples of second plates coupled to first plates, including specific arrangements and examples of wick structures embodying innovative concepts. More particularly, but not exclusively, such innovative principles are described in relation to selected examples of evaporator wick structures and condenser wick structures, and their dispositions within the vapor chambers, and well-known functions or constructions are not described in detail for purposes of succinctness and clarity. Nonetheless, the disclosed principles can be incorporated in various other embodiments of different evaporator wick structures and condenser wick structures, and their dispositions within the vapor chambers to achieve any of a variety of desired outcomes, characteristics, and/or performance criteria.

Thus, evaporator wick structures and condenser wick structures, and their dispositions within the vapor chambers having attributes different from those specific examples discussed herein can embody of the innovative principles and can be used in applications not described herein in detail.

Example embodiments as disclosed herein are directed to vapor chambers, wherein a surface of the vapor chamber is thermally coupled to an electronic component, transporting heat away therefrom. In response to the heat, a portion of the working fluid transitions from a liquid phase to a gas phase. The gas portion of the working fluid rises and distributes the heat substantially along the second plate and heat pipes of the vapor chamber. The second plate and heat pipes transfer the heat to ambient air outside of the vapor chamber. The working fluid condenses back into a liquid in response to conducting the heat to the second plate and heat pipes and the liquid returns to a center of the vapor chamber where the cycle is repeated.

The vapor chambers may be configured within an electric or electronics system that includes heat producing electronic components to be cooled.

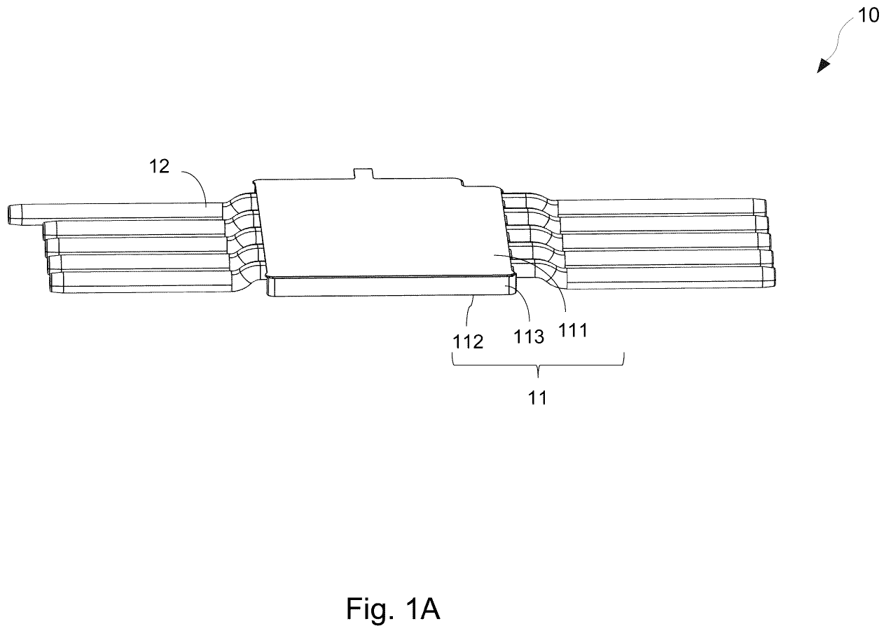

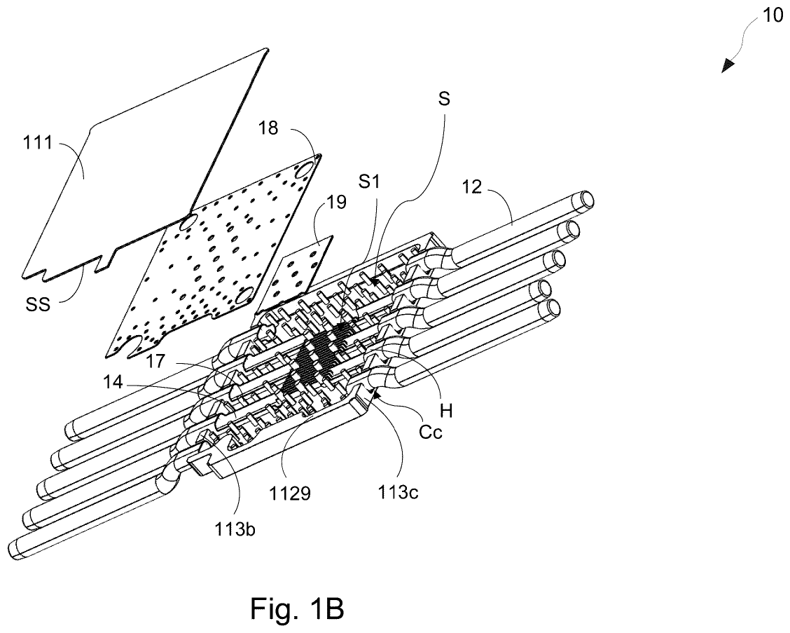

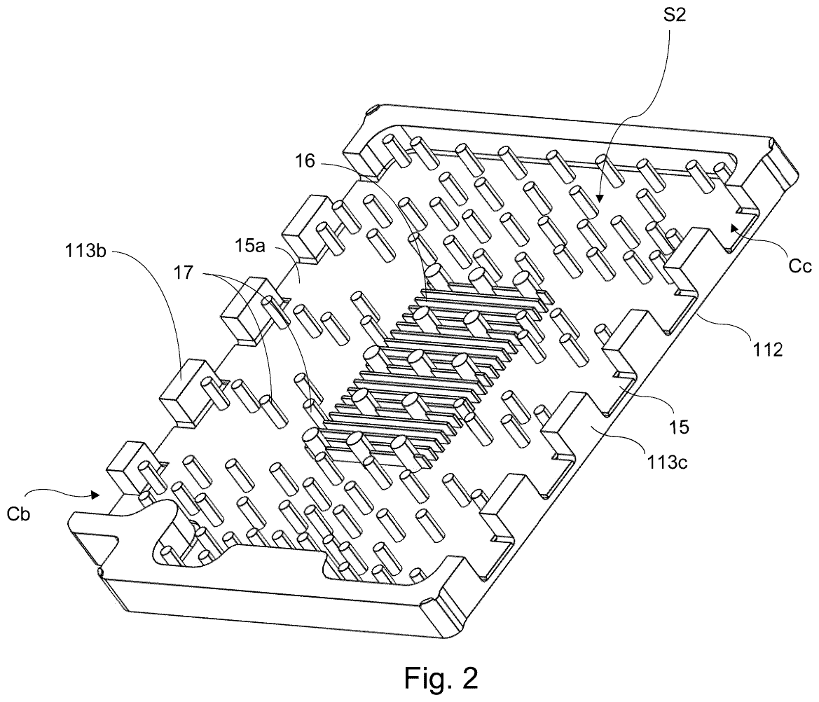

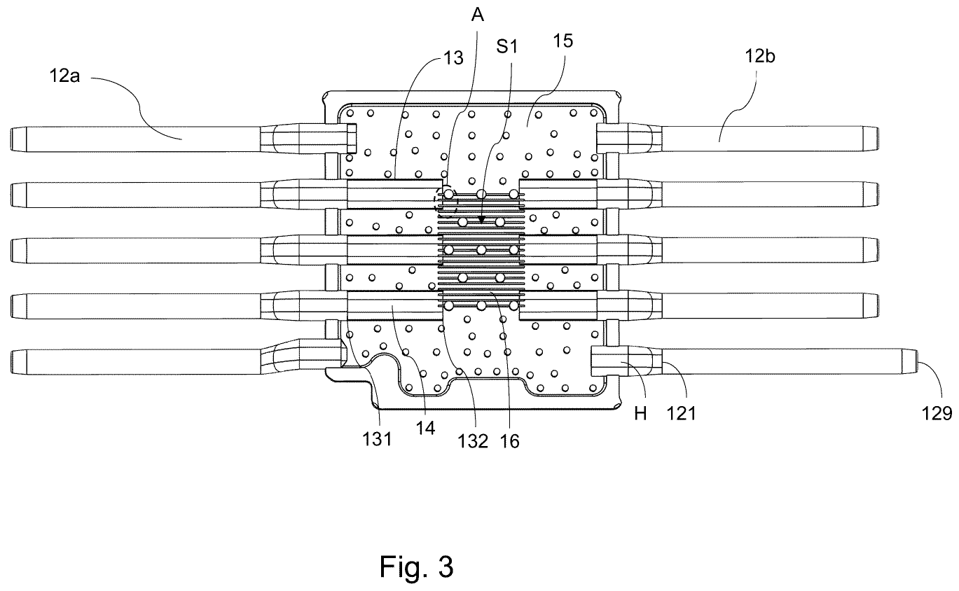

FIGS. 1A, 1B, and 2 an example of a vapor chamber 10. The vapor chamber 10 includes a chamber 11 and heat pipes 12. The chamber 11 includes a first plate 112, an evaporator wick structure 15, a second plate 111, and a condenser wick structure 18. The first plate 112 includes a first outer surface (not shown), a first inner surface (now shown), chamber walls 113, and support structures 17. In some embodiments, the chamber walls 113 and support structures 17 can also be separate parts from the first plate 112. The support structures 17 is coupled to and extends from the first inner surface. The chamber walls 113 surrounds and/or extends from a perimeter of the first inner surface. The chamber walls 113 includes a first chamber wall portions, which include first plate perimeter ledges 1129 disposed on opposite ends of the perimeter of the first plate 112. The chamber walls 113 includes a second chamber wall portion 113b and a third chamber wall portion 113c opposite the second chamber wall portion 113b. The second chamber wall portion 113b includes cut outs Cb, and the third chamber wall portion 113c includes cut outs Cc. The evaporator wick structure 15 includes a first surface wick portion 15a disposed on the first inner surface. The second plate 111 includes a second inner surface (not shown), a second outer surface, and a second plate perimeter portion SS. The second plate perimeter portion surrounds the second plate 111 and the second plate perimeter portion SS is coupled to the first plate perimeter ledge 1129. The condenser wick structure 18 is disposed on the second inner surface. The heat pipes 12 includes first subset of heat pipes 12a and second subset of heat pipes 12b (see FIG. 3). Each of the heat pipes 12 respectively includes an inner chamber surface (not shown in FIG. 1A, 1B, or, 2), which can have a pipe wick structure or be covered with a pipe wick structure (not shown in FIG. 1A, 1B, or 2). Each of the first subset of heat pipes 12a is disposed respectively through each of the cut outs Cb and forms a sealing connection with the second chamber wall portion 113b and the second plate perimeter portion SS, and extends in a respective direction relative to the second chamber wall portion 113b. Each of the second subset of heat pipes 12b is disposed respectively through each of the cut outs Cc and forms a sealing connection with the third chamber wall portion 113c and the second plate perimeter portion SS, and extends in a respective direction relative to the third chamber wall portion 113c. The pipe wick structure is coupled to the evaporator wick structure 15.

In some embodiments, the first plate 112, including the chamber walls 113, and the second plate 111 define an interior cavity S. The interior cavity S includes a heat exchange portion S1 and an evaporation portion S2. In one embodiment, the heat exchange portion S1 is disposed in around the center of the interior cavity S. The remaining portion of the interior cavity S is the evaporation portion S2 surrounding the heat exchange portion S1. Each of the heat pipes 12 is respectively fluidly coupled to the interior cavity S.

In some embodiments, the vapor chamber 10 further includes a core condenser wick structure 19. The core condenser wick structure 19 is coupled to, and extends inwardly from, the condenser wick structure 18. The core condenser wick structure 19 is disposed in the heat transfer portion exchange portion S1.

In some embodiments, the support structures 17 abuts the second inner surface.

In some embodiments, each of the heat pipes 12 respectively includes a closed end 129, an open end 121, and a connector portion H. The open end 121 is opposite the closed end 129 and the connector portion H couples the open end 121 with the interior cavity S. The connector portion H of each of the first subset of heat pipes 12a are disposed through the respective cut outs Cb and the second plate perimeter portion. The connector portion H of the second set of heat pipes 12b are disposed through the respective cut outs Cc and the second plate perimeter portion. In some embodiments, the connector portion H of each of the heat pipes 12 includes a flat (rectangular, square or other polygonal) portion of the heat pipe, and in other embodiments the connector portion H of each of the heat pipes 12 includes a round portion of the heat pipes.

In some embodiments, the first plate 112 includes heat exchanger structures 16, which include heat exchanger elements, such as heat fins, in this example. Each of the heat exchanger structures 16 is coupled to and extends from the first inner surface in the heat exchanger portion S1. One or more heat exchanger structures 16 is integrally formed with one or more support structures 17.

In some embodiments, each of the heat exchanger structures 16 may be elongated. Each of the heat exchanger structures 16 is disposed in parallel on the first inner surface in the heat exchanger portion S1 with the longitudinal direction of the heat pipes 12. In other embodiments, the heat exchanger structures 16 are not disposed in parallel with each other on the first inner surface in the heat transfer exchanger S1.

In some embodiments, one or more heat pipes 12 each include an extension portion 13. The extension portion 13 includes a bottom surface 133 and an exposed inner chamber surface (not shown). The exposed inner surface is on an opposite side of the bottom surface 133 and is not enclosed in the heat pipe 12. The pipe wick structure (not shown) includes a pipe wick portion (not shown) and an extension wick portion 14. The pipe wick portion is disposed on the inner chamber surface. The extension wick portion 14 is disposed on the exposed inner chamber surface. The extension wick portion 14 couples the pipe wick portion with the evaporator wick structure 15. In some embodiments, the extension portion 13 is formed by cutting off a respective top end portion of the heat pipes 12. In some embodiments, the extension portion 13 is formed by coupling to the connector portion H by, as an example, welding.

In some embodiments, the bottom surface 133 is coupled to the first inner surface. In some embodiments, the bottom surface 133 is coupled to the first inner surface, as an example, welding. In other embodiments, the extension wick portion 14 is integrally formed with the evaporator wick structure 15. In some embodiments, the extension wick portion 14 is connected with the evaporator wick structure 15 via, as an example, metal bonding.

In some embodiments, the bottom surface 133 is coupled to the evaporator wick structure 15. In some embodiments, the extension wick portion 14 is integrally formed with the pipe wick portion.

In some embodiments, the evaporator wick structure 15 includes a heat exchanger wick portion. The heat exchanger wick portion is disposed on the heat exchanger structures 16. The extension wick portion 14 is coupled to the heat exchanger wick portion.

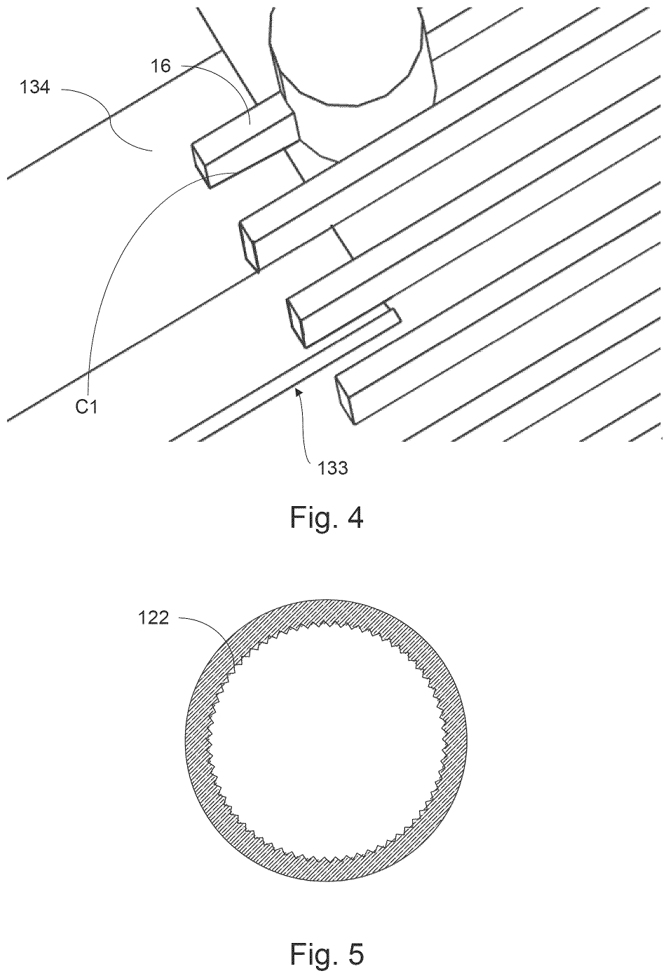

FIGS. 3 and 4 illustrate other embodiments, with a detailed view, of the area marked “A” of heat pipes 12 and the first plate 112 of the vapor chamber 10. In some embodiments, each of the extension portion 13 is respectively coupled to the heat exchanger structures 16. In some embodiments, the extension portion 13 includes a connector end 131 and a cavity end 132. The cavity end 132 includes a base cut out C1. The connector end 131 is coupled to the connector portion H, and the base cut out C1 is connected with the heat exchanger structures 16. In some embodiments, the cavity end 132 is respectively coupled to the heat exchanger structures 16 via an adhesive or by welding.

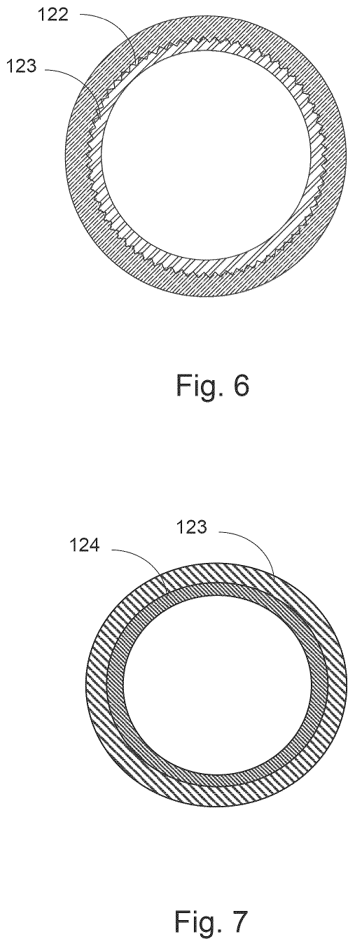

FIGS. 5, 6 and 7 are detailed views of wick structures of the inner pipe wick. Similar wick structures can also be used for the evaporator wick structure 15 and condenser wick structure 18. FIG. 5 is a detailed view of a grooved wick 122, FIG. 6 is a detailed view of a sintered powder wick 123 on a grooved wick 122, and FIG. 7 is a detailed view of a flat wick structure 124 on a sintered powder wick 123. In some embodiments, the evaporator wick structure 15 includes a grooved wick, a sintered metal powder wick, a metal mesh wick, or a sintered ceramic powder wick, or any combination of the foregoing wicks. In some embodiments, the condenser wick structure 18 includes a grooved wick, a sintered metal powder wick, a metal mesh wick, a sintered ceramic powder wick, or any combination of the foregoing wicks. In some embodiments, the pipe wick structure includes a grooved wick, a sintered metal powder wick, a metal mesh wick, a sintered ceramic powder wick, any combination of the foregoing wicks. In some embodiments, a material of the evaporator wick structure 15, condenser wick structure 18, and pipe wick structure can be gold, silver, copper or iron.

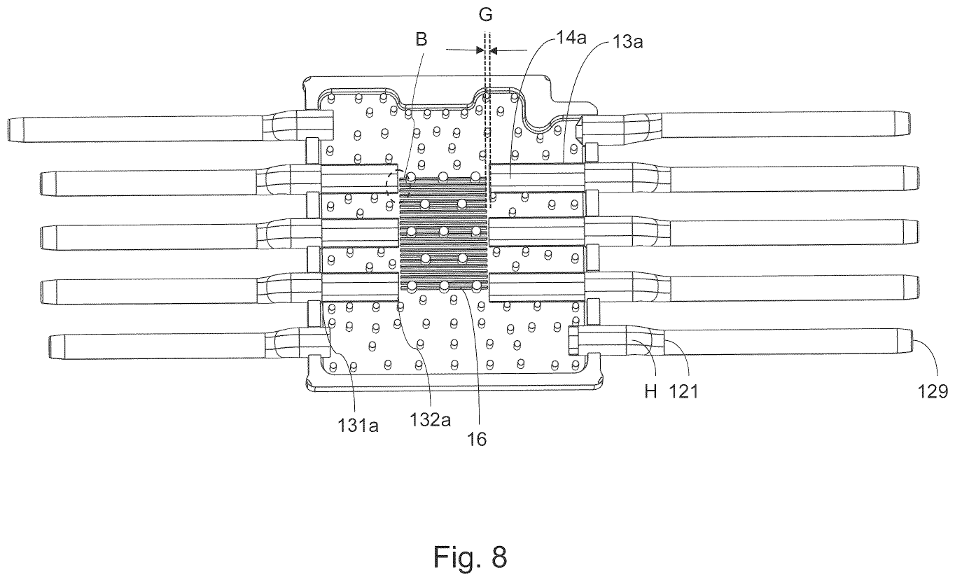

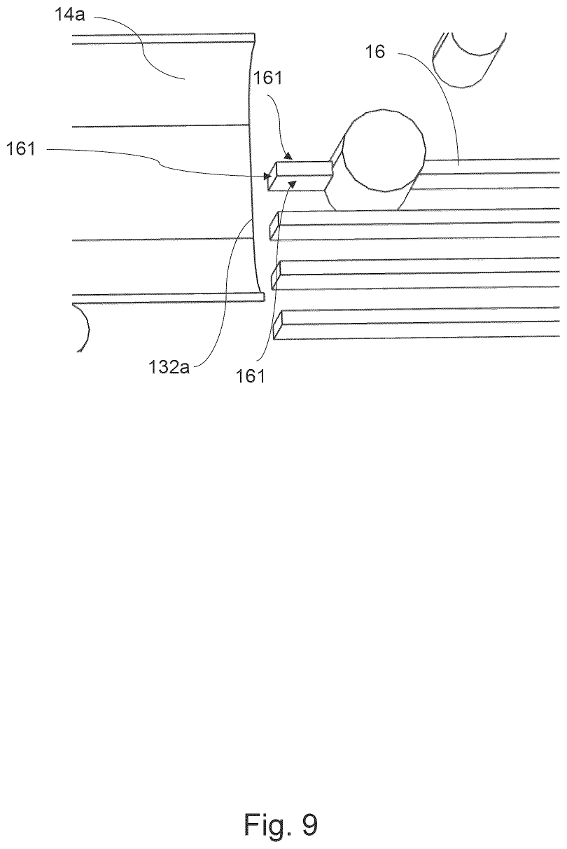

FIGS. 8 and 9 illustrate another embodiment, with a detailed view of the area marked “B” of heat pipes 12 and the first plate 112 of the vapor chamber 10. In some embodiments, the vapor chamber 10 further includes a vapor gap G. The vapor gap G is disposed between the extension portion 13a and the heat exchanger structures 16. In some embodiments, each of the heat exchanger structures 16 includes outer surfaces 161. In some embodiments, the exchanger wick portion is disposed one or more of the outer surfaces 161 of the heat exchanger structures 16.

The vapor chamber 10 of the present disclosure increases surface area for heat exchange, thereby increasing working fluid pathways to enhance heat dissipation efficiency. The condenser wick structure 18 speeds up transport of condensed working fluid back to the first inner surface opposite the heat source. Moreover, the heat pipes 12 increases surface area within the evaporation portion S2 and even further increases condensation surfaces, improving thermal performance of the vapor chamber 10. Furthermore, the core condenser wick structure 19 extends from the condenser wick structure 18 in the heat exchanger portion S1, to even further accelerate transport of the condensed working fluid. Also, the first surface wick portion 15 and the base structure wick portion of the evaporator wick structure 15 further enhances transport of condensed working fluid back to the first inner surface. Moreover, the extension wick portion 14 of the extension portion 13, coupled to the pipe wick portion and the evaporator wick structure 15, further drives condensed working fluid to flow from the heat pipes 12 to the heat exchanger wick portion and the evaporator wick structure 15, adding to the effectiveness of the vapor chamber 10 to dissipate heat via the phase change (liquid-vapor-liquid) mechanism, enhancing the thermal performance of the vapor chamber 10, as an example, by as much as 20% to 30%. Thus, overheating of electronic components of thin and compact electronic device is prevented as the generated heat of the electronic component is more efficiently distributed along the vapor chamber 10 and the condensed working fluid is more efficiently transported back to the first inner surface opposite the heat source to adequately cool the electronic components of the electronic device.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean than one of the element that it introduces.

1. A vapor chamber, comprising:
a first plate including a first outer surface, a first inner surface, and a first plate perimeter portion;
a chamber wall located along the first perimeter portion, extending from the first inner surface, and defining a plurality of openings;
a plurality of support structures extending from the first inner surface;
an evaporator wick structure disposed on the first inner surface;
a second plate including a second outer surface, a second inner surface opposing the first inner surface and having a second plate perimeter portion coupled to the chamber wall;
a condenser wick structure disposed on the second inner surface; and
a plurality of heat pipes, each extending through a respective opening defined in the chamber wall and including an inner pipe wick structure coupled to the evaporator wick structure.

2. The vapor chamber of claim 1, wherein the first plate, second plate, and chamber wall define an interior cavity including a heat exchanger portion and a evaporation portion, the heat exchanger portion disposed in a center portion of the interior cavity, the evaporation portion surrounding the heat exchanger portion in the interior cavity, wherein each or the plurality of heat pipes is fluidly coupled to the interior cavity.

3. The vapor chamber of claim 2, further comprising a core condenser wick structure coupled to the condenser wick and disposed in the interior cavity, and being disposed in the heat exchanger portion.

4. The vapor chamber of claim 2, wherein each of the plurality of heat pipes includes a closed end disposed outside the interior cavity, an open end disposed in the interior cavity, and a connector portion coupling the open end of the heat pipe with the interior cavity.

5. The vapor chamber of claim 4, wherein the first plate includes a plurality of heat exchanger structures extending from the first inner surface and disposed in the heat exchanger portion.

6. The vapor chamber of claim 5, wherein the heat exchange structures being integrally formed with the plurality of support structures.

7. The vapor chamber of claim 5, wherein the heat exchanger structures are elongated and disposed in parallel to the heat pipes.

8. The vapor chamber of claim 4, wherein at least one of the heat pipes includes an extension portion at the opening end, the extension portion includes a bottom surface and an exposed portion of the inner pipe wick structure, the exposed portion not being enclosed within the heat pipe and being coupled to the pipe wick portion enclosed in the heat pipe and coupled to the evaporator wick structure.

9. The vapor chamber of claim 8, wherein the bottom surface of the extension portion is coupled to the first inner surface.

10. The vapor chamber of claim 8, wherein the bottom surface of the extension portion is coupled to the evaporator wick structure.

11. The vapor chamber of claim 8, wherein the evaporator wick structure includes a heat exchanger wick portion disposed on the heat exchanger structures.

12. The vapor chamber of claim 11, wherein each of the extension portion is coupled to a respective set of the heat exchanger structures.

13. The vapor chamber of claim 12, wherein each of the extension portion includes a connector end and a cavity end, the connector end coupled to the connector portion, and the cavity end defining at least one a base cut out coupling a respective one of the heat exchanger structures.

14. The vapor chamber of claim 8, wherein the extension portion and the heat exchanger structures are separated by a vapor gap.

15. The vapor chamber of claim 1, wherein the support structures abut the second inner surface.

16. The vapor chamber of claim 1, wherein the evaporator wick structure includes a grooved wick, a sintered metal powder wick, a metal mesh wick, a sintered ceramic powder wick, or a combination thereof.

17. The vapor chamber of claim 1, wherein the condenser wick structure includes a grooved wick, a sintered metal powder wick, a metal mesh wick, a sintered ceramic powder wick, or a combination thereof.

18. The vapor chamber of claim 1, wherein the inner pipe wick structure includes a grooved wick, a sintered metal powder wick, a metal mesh wick, a sintered ceramic powder wick, or a combination thereof.
